(19) United States
(12) Patent Application Publication
(10) Pub. No.: US 2026/0075775 A1
(43) Pub. Date: Mar. 12, 2026

(54) COUPLED DATA CENTER COOLING AND LNG REGASIFICATION APPARATUS AND METHOD OF USE THEREOF

(71) Applicants: Brian Cohen, San Juan Capistrano, CA (US); Daniel Robert Hideki Cohen, San Juan Capistrano, CA (US); Ryan Thomas Cohen, San Juan Capistrano, CA (US); Greta Cohen, Laguna Beach, CA (US); W. Davis Lee, Rockport, ME (US)

(72) Inventors: Brian Cohen, San Juan Capistrano, CA (US); Daniel Robert Hideki Cohen, San Juan Capistrano, CA (US); Ryan Thomas Cohen, San Juan Capistrano, CA (US); Greta Cohen, Laguna Beach, CA (US); W. Davis Lee, Rockport, ME (US)

(21) Appl. No.: 19/059,624

(22) Filed: Feb. 21, 2025

Related U.S. Application Data
(60) Provisional application No. 63/693,443, filed on Sep. 11, 2024.

(51) Int. Cl. H05K 7/20; F17C 5/02

(52) U.S. Cl. CPC H05K 7/20827; F17C 5/02; F17C 2221/033; F17C 2227/0306; F17C 2265/05; F17C 2265/066; F17C 2270/05

(57) ABSTRACT

The invention comprises a coupled data center cooling/liquid natural gas (LNG) regasification heating and cooling apparatus and method of use thereof. For example, a method is described for cooling a data center, comprising the steps of: (1) transferring heat from the data center to a liquid phase combustible refrigerant and (2) phase changing the liquid phase combustible refrigerant, carried by the trailer, to a gas phase combustible refrigerant, at least fifty percent of an enthalpy of vaporization energy used in the step of phase changing transferred to the gas phase combustible refrigerant in the step of transferring, the gas phase combustible refrigerant comprising an energy density of greater than 10,000 kJ/kg. Optionally, the step of phase changing boils a liquefied natural gas (LNG), carried by the trailer, to a gas phase natural gas (NG).

### CROSS-REFERENCES TO RELATED APPLICATIONS

This application claims benefit of U.S. provisional patent application No. 63/693,443 filed Sep. 11, 2024.

### BACKGROUND OF THE INVENTION

### Field of the Invention

The invention relates generally to a coupled data center cooling/liquid natural gas (LNG) regasification heating and cooling apparatus and method of use thereof.

### Discussion of the Prior Art

### Problem

There exists in the art a need for cooling data centers and/or heating liquid natural gas (LNG) in a regasification step, such as to form natural gas.

### SUMMARY OF THE INVENTION

The invention comprises coupling energy requirements of a data center and liquid natural gas (LNG) regasification.

### DESCRIPTION OF THE FIGURES

A more complete understanding of the present invention is derived by referring to the detailed description and claims when considered in connection with the Figures, wherein like reference numbers refer to similar items throughout the Figures.

FIG. 1 illustrates a data center energy management system;

FIG. 2 illustrates types of processing units;

FIG. 3 illustrates a proximate heat transfer system from a processing unit to a liquefied natural gas;

FIG. 4 illustrates an internal heat transfer system between a processing unit and a liquefied natural gas;

FIG. 5 illustrates a remote energy transfer system between a processing unit and a liquefied natural gas;

FIG. 6A, FIG. 6B, and FIG. 6C illustrate vehicle assisted server farm/server/processing unit heat transfer systems, FIG. 6D illustrates a ship assisted processing unit heat transfer system, and FIG. 6E illustrates a pipeline assisted processing unit heat transfer system;

FIG. 7 illustrates a circulating coolant data center heat management system;

FIG. 8 illustrates a regasification cooling system with optional external power supplies; and

FIG. 9 illustrates use of backup power for running/cooling a data center.

Elements and steps in the figures are illustrated for simplicity and clarity and have not necessarily been rendered according to any particular sequence. For example, steps that are performed concurrently or in different order are illustrated in the figures to help improve understanding of embodiments of the present invention.

### DETAILED DESCRIPTION OF THE INVENTION

The invention comprises a coupled data center cooling/liquid natural gas (LNG) regasification heating and cooling apparatus and method of use thereof. For example, a method is described for cooling a data center, comprising the steps of: (1) transferring heat from the data center to a liquid phase combustible refrigerant and (2) phase changing the liquid phase combustible refrigerant, carried by the trailer, to a gas phase combustible refrigerant, at least fifty percent of an enthalpy of vaporization energy used in the step of phase changing transferred to the gas phase combustible refrigerant in the step of transferring, the gas phase combustible refrigerant comprising an energy density of greater than 10,000 kJ/kg. Optionally, the step of phase changing boils a liquefied natural gas (LNG), carried by the trailer, to a gas phase natural gas (NG).

### Introduction

Generally, data centers use a tremendous amount of energy, and much of this is dissipated as waste heat. It is estimated, that in 2023, 7.4 GW or ˜1-1.3% of the world's power was used for data centers. With the advent of AI and advanced computing centers, data center power consumption is only considered to grow. Generally, the waste heat from data centers and/or processing units therein is transferred to the local environment by one method or another, this makes data centers in cooler climates significantly more power efficient than those in warmer climates. In cooler climates, such as Iceland or Ireland, a data center might use 10 to 20% of the of the total power consumption for cooling of the processors. In a hotter climate, such as Dubai or Singapore, a data center might require 50% of the total power consumption for cooling the processors.

If re-gasification of liquid natural gas were performed at and/or in close proximity to a data center, the data center optionally provides a ready heat source for the regasification of a fuel, such as regasification of liquefied natural gas (LNG), which is also referred to as liquid natural gas, and/or worded another way, the regasification optionally provides cooling for the data center. These two functions thus provide a symbiotic relationship between LNG re-gasification and data center cooling.

Optionally and preferably, the data center uses some of the re-gasified natural gas, resultant from heating the liquefied natural gas, to generate power for computation requirements of the data center. Natural gas generators can be found from a few hundred kW to 100 MW. Optionally, this makes the data center a self-sufficient unit working with the liquefied natural gas regasification facility, such as it need not be connected to an external power grid.

Heat transfer from a data center to a combustible refrigerant to aid in cooling of the data center is further described herein.

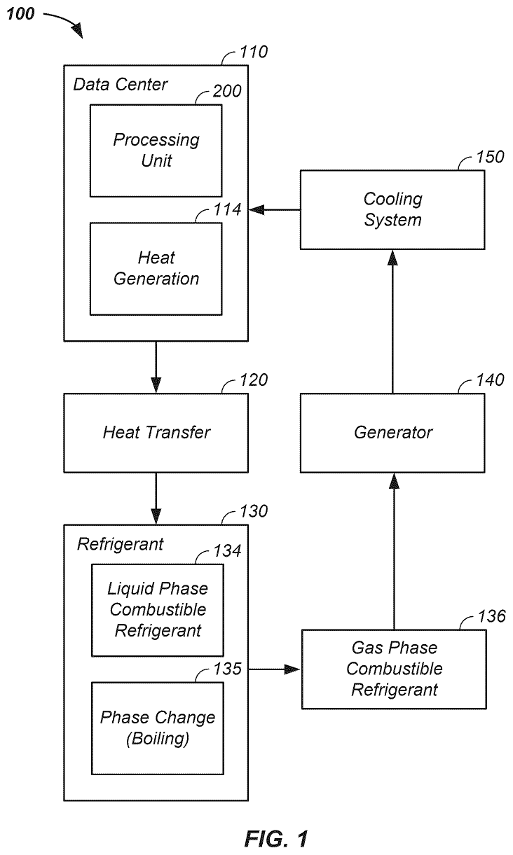

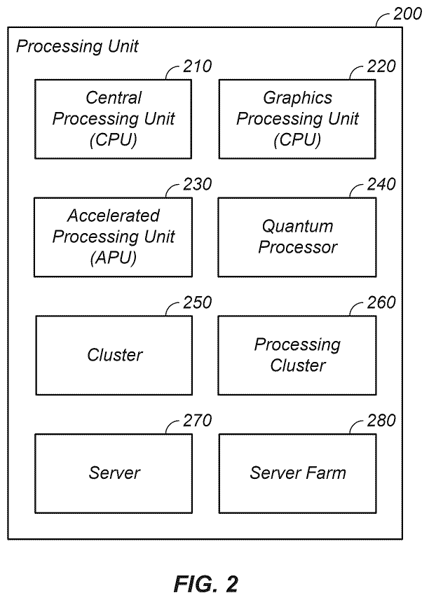

Referring now to FIG. 1, an energy management system 100 is described, such as for cooling and/or powering a data center. Generally, a data center 110 comprises a processing unit 200, or typically many processing units, that generate heat 114. The processing unit 200 is further described, infra. In one embodiment, at least a portion of the heat generated 114 in the data center 110, such as from a plurality of processing units 200, is transferred 120 to a refrigerant 130. Optionally and preferably, at least a portion of generated heat 114 is transferred as heat 120 from the processing unit 200 to the refrigerant 130, which results in a phase change 135 of the refrigerant from a liquid phase to a gas phase. For example, the heat transfer 120 optionally and preferably boils the refrigerant 130. More particularly, optionally and preferably, the heat transfer 120 from the processing unit 200 to the refrigerant 130 results in greater than 10, 20, 30, 40, 50, 60, 70, 80, or 90 percent of the energy of an enthalpy of vaporization of the refrigerant 130; resultant in the refrigerant 130 undergoing a phase change from a liquid state to a gas state. The enthalpy of vaporization, also known as the heat of vaporization or heat of evaporation, is the amount of energy that must be added to a liquid substance to transform a quantity of that substance into a gas. Stated again, the use of heat transfer 120 from the data center 110 to the refrigerant 130 moves heat from the data center 110, which cools the data center 110 and/or cools the processing unit(s) 114 therein. Optionally and preferably, the refrigerant 130, when undergoing the phase change from liquid to gas, changes from a liquid phase combustible refrigerant 134 to a gas phase combustible refrigerant 136. Herein, a combustible refrigerant, such as the liquid phase combustible refrigerant 134 and/or the gas phase combustible refrigerant 136 comprises an energy density of greater than 10,000, 20,000, 30,000, and/or 40,000 kJ/kg. For comparison, a chlorofluorocarbon refrigerant has an energy density of <10,000 kJ/kg. Further, optionally and preferably, the refrigerant 130 has a chloride and/or fluoride concentration of less than 30, 20, 10, 5, 2, or 1 percent by mass. Optionally, the resultant gas phase combustible refrigerant 136 is used to at least partially power a generator 140. Power from the generator 140 is optionally used for any purpose, but in one example power from the generator 140 is at least partially used to drive a cooling system 150, where the cooling system 150 is optionally used to cool the data center 110 and/or to power the processing unit(s) 200 therein. The energy management system 100 is further described, infra.

Referring now to FIG. 2, the data center 110 and the processing unit(s) 200 are further described. Generally, in some cases a server farm is an example of the data center 110. Typically, the data center 110/server farm comprises a plurality of processing units, such as greater than 1, 10, 100, 1000, 5000, or 10,000 processing units/processors/computer processors. Each processing unit is optionally a central processing unit (CPU) 210, a graphics processing unit (GPU) 220, an accelerated processing unit (APU) 230, a quantum processor 240 and/or a computer processor. Groups of processing units are referred to as a cluster 250, such as a cluster of processors, a processing cluster 260, and/or processors of a server 270 and/or a server farm 280.

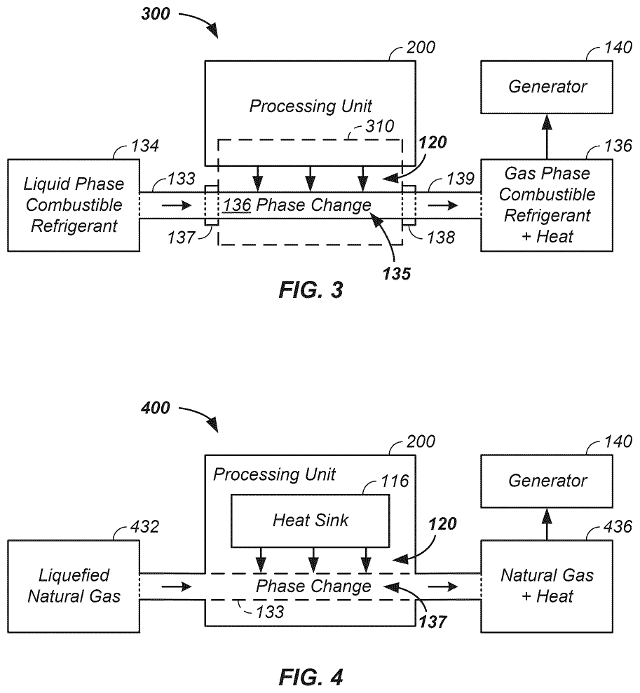

Referring now to FIGS. 3-5, heat transfer 120 is further described. More particularly, three examples of heat transfer 120 are described, a proximate heat transfer system 300, an internal heat transfer system 400, and a remote heat transfer system 500, where elements of any of the described heat transfer systems are optionally and preferably interchangeable and/or used in other heat transfer systems.

Referring now to FIG. 3, a proximate heat transfer system 300 is described, where the processing unit 200 is proximate to a phase change 135 of the liquid phase combustible refrigerant 134 to the gas phase combustible refrigerant 136, such as the phase change being less than 200, 100, 50, 25, 10, 5, 4, 3, 2, 1, or 0.5 feet from the processing unit 200 and/or a heat sink coupled to the processing unit 200. As illustrated, the liquid phase combustible refrigerant 134 passes into and/or passes at least partially through a heat transfer pipe 133 of any cross-sectional geometry. The heat transfer pipe extends through a heat exchanger 310 and/or is positioned next to and preferably in contact with a heat sink connected to the processor. The phase change 135 optionally and preferably occurs in a phase change chamber 136, where the phase change chamber is optionally connected with a first connector 137 to a supply of the liquid phase combustible refrigerant 134 and/or a second connector 138 to an output path 139/tube through which the gas phase combustible refrigerant flows.

In the heat exchanger 310, at least partial heat transfer 120 of the heat generated 114 by the processing unit 200 to the refrigerant 130 occurs. Again, the heat transfer 120 provides greater than 10, 20, 30, 40, 50, 60, 70, 80, or 90 percent of the energy required to phase change 135 the liquid phase combustible refrigerant 134 to the gas phase combustible refrigerant 136. As illustrated, the gas phase combustible refrigerant 136 can be thought of as carrying the transferred heat 120, which results in cooling of the data center 110, cooling of the processing unit 200, and/or cooling of a heat sink lined to the processing unit(s) 200.

Referring now to FIG. 4, an internal heat transfer system 400 is described. Generally, internal heat transfer system 400 has any one or more of the conditions of the proximate heat transfer system 300 and vice versa, except that in the internal heat transfer system 300 the processing unit 200 transfers heat to the refrigerant 130 within a housing. As illustrated, heat transfer 120 from the processing unit 200 to a heat sink 116 occurs and heat is transferred from the heat sink 116 to the heat transfer pipe 133 and results in the phase change 135 of the liquid phase combustible refrigerant 134 to the gas phase combustible refrigerant 136. Optionally and preferably, the heat sink 116 is also implemented in the proximate heat transfer system 300, such as to pull heat away from the processing unit 200. Similarly, optionally and preferably, the heat exchanger 310 of the proximate heat transfer system 300 is implemented in the internal heat transfer system 400.

Referring again to FIG. 3 and FIG. 4, a plurality of processing unit(s) 200 are optionally and preferably linked to a common heat sink, such as a piece of metal, and/or are linked to a common heat exchanger.

Still referring to FIG. 4, for clarity of presentation and without loss of generality, a liquefied natural gas (LNG) is a preferred embodiment of a liquid phase combustible refrigerant 134. Stated again, a liquefied natural gas 432, commonly referred to as LNG, is used as an example of the liquid phase combustible refrigerant 134. Similarly, a natural gas 436 or NG or natural gas (g) is used as an example of the gas phase combustible refrigerant 136. Herein, a liquefied natural gas (LNG) 432 is a natural gas 436 that has been previously cooled to a liquid state, such as at about −260° F., such as for shipping or storage. As illustrated gasification 137 of the liquefied natural gas 432 is an example of the phase change 135. Optionally, a liquefied combustible gas is optionally used in place of the liquid phase combustible refrigerant, such as liquefied ethanol, a liquefied alcohol, a liquefied biofuel, a liquefied petroleum, a liquefied petroleum gas, and/or a liquefied hydrocarbon, where the hydrocarbon comprises greater than 50, 60, 70, 80, or 90 percent of a form of carbon and hydrogen by mass.

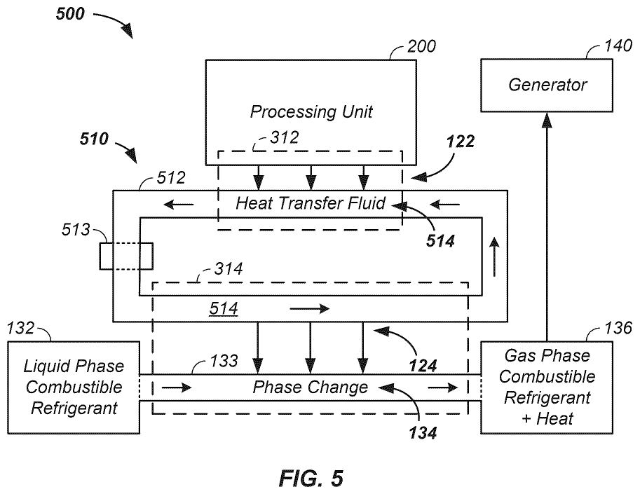

Referring now to FIG. 5, a remote heat transfer system 500 is described. Generally, the heat exchanger 310 is described using multiple heat exchangers, such as greater than 1, 2, 3, 4, or 5 heat exchangers. Similarly, the heat exchange step/heat transfer 120 is described using multiple heat exchange steps, such as greater than 1, 2, 3, 4, or 5 heat exchange steps. In one example, as illustrated, a first heat exchanger 312 or first heat exchange element is used in a first heat exchange step 122 to transfer heat from the processing unit 200 to at least one intermediate heat transfer system 510. Here, the intermediate heat transfer system 510 is illustrated with a heat transfer pipe 512 of any cross-sectional geometry. Optionally and preferable the heat transfer system uses greater then 0, 1, 2, 3, 5, 10, 50, or 100 heat transfer pipes and/or heat sinks. As illustrated, a heat transfer fluid 514 and/or heat sinks moves and/or transfers heat, such as with an optional heat transfer fluid pump 513, to a second heat exchanger 314 or second heat exchange element, which are also optionally heat exchange pipes and/or heat sinks. As described, supra, the liquid phase combustible refrigerant 134 undergoes a phase change 135 from a liquefied state to form the gas phase combustible refrigerant 136. Again, greater than 10, 20, 30, 40, 50, 60, 70, 80, or 90 percent of the energy required to phase change 135 the liquid phase combustible refrigerant 134 to the gas phase combustible refrigerant 136 originates as heat generated 114 in the data center 110 and/or processing unit 200, where the heat generation 114 in the data center 110 is transferred to the phase change 135 indirectly via the intermediate heat transfer system 510. Several examples of an intermediate heat transfer system 510 follow.

### Example I

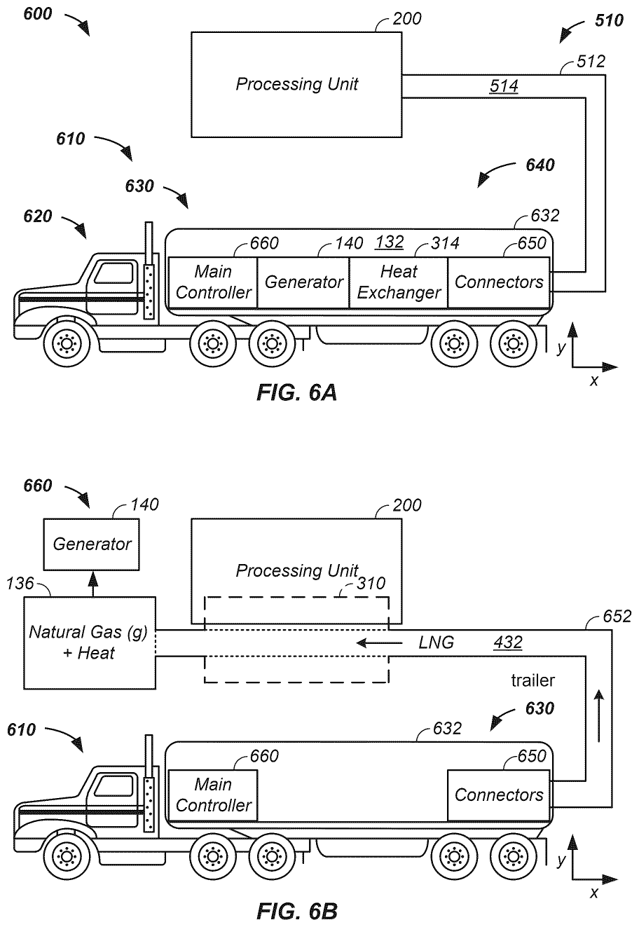

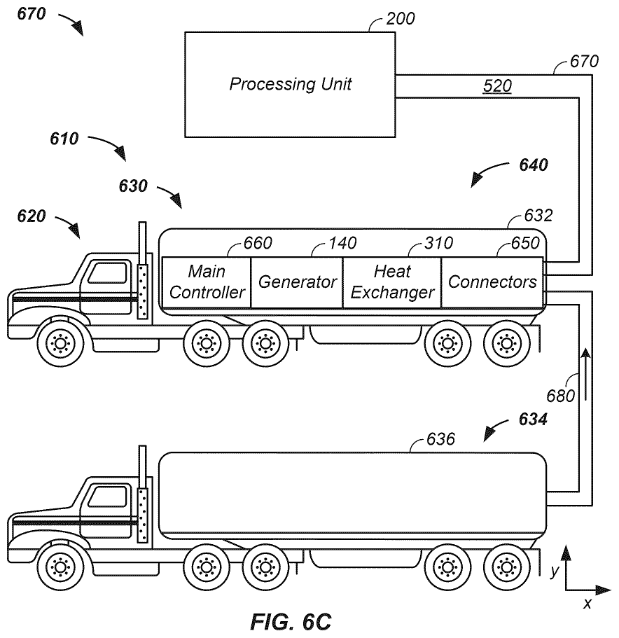

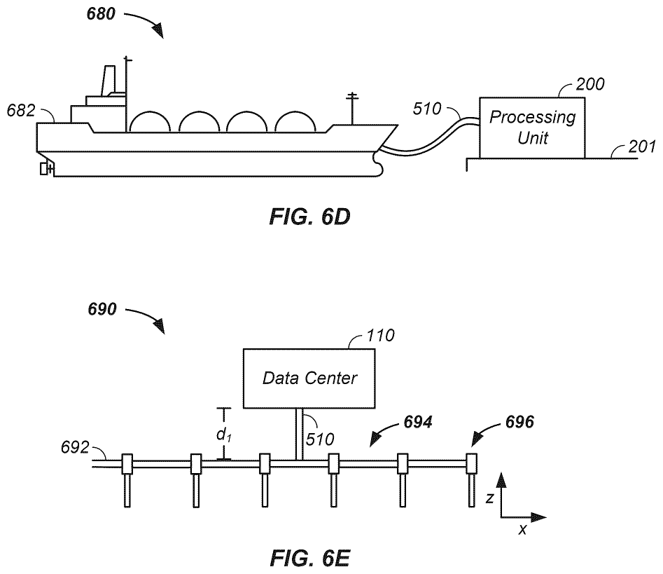

Referring now to FIG. 6A, a first example of an intermediate heat transfer system 510 is a vehicle assisted heat transfer system 600. As illustrated, the data center 110 and/or processing unit 200 therein generates heat 114, as described supra. Here, the intermediate heat transfer system 510, heat transfer pipe(s) 512, and/or heat transfer fluid 514 function to transfer heat 120 from the data center 110 and/or processing unit 200 to a liquid phase combustible refrigerant transfer system 610 or a liquefied natural gas holding container and/or storage container. Herein, for clarity of presentation and without loss of generality the liquid phase combustible refrigerant transfer system 610 is illustrated as a tractor trailer comprising at least one of: a tractor 620 or a trailer 630. In this example, the trailer 630 comprises a first storage tank 632 holding the liquid phase combustible refrigerant 134. Essentially, a heat exchanger 310, such as the second heat exchanger 314, is one element of a set of on-board elements 640 positioned on, in, and/or within 100 feet of the liquid phase combustible refrigerant transfer system 610. When on-board the trailer 630, the second heat exchanger is optionally connected to the trailer with a fastening unit, holder, and/or platform. The second heat exchanger 314 is optionally a phase change container, phase change pipe, and/or any element holding the liquid phase combustible refrigerant 132 when is phase changes into the gas phase combustible refrigerant 136 and/or is an element configured to transfer heat from the data center 110 to the liquid phase combustible refrigerant 132. For example, as illustrated, the second heat exchanger 314 is positioned on the trailer 630 of the tractor trailer. The second heat exchanger 314 is used to transfer heat from the intermediate heat transfer system 510, such as heat from the heat transfer fluid 514, to the liquid phase combustible refrigerant 134 to power the above described phase change 135, which occurs in this example on the trailer 630 or within 500 feet of the trailer. The intermediate heat transfer system 510 is optionally and preferably any pipe of containment system holding a heat transfer fluid, such as in a circulating path between the data center 110 and/or processing unit 200 thereof to a position of the phase change. Optionally and preferably, a connector 650 connects one or more elements of the intermediate heat transfer system 510 to the trailer 630 and ultimately the second heat exchanger 314 thereon. The on-board elements 640 on the tractor-trailer and/or the trailer 630 optionally include the generator 140 and/or a main controller 660, where the main controller 660 optionally and preferably is a computer system used to control any element of the heat transfer process from the generated heat 114 of the data center 110/processing unit 200 to the phase change 135 of the liquid phase combustible refrigerant 134 to the gas phase combustible refrigerant 136. Again, heat from the data center 110 and/or processing unit 200 is used to phase change 135 the liquid phase combustible refrigerant 134, such as on the trailer 630.

### Example II

In a second example, referring now to FIG. 6B, the vehicle assisted heat transfer system 600 comprises a system of moving 660 the liquid phase combustible refrigerant 134 to the data center 110/processing unit 200. For clarity of presentation and without loss of generality, a trailer 630 is used as an example of the liquid phase combustible refrigerant transfer system 610. Further, for clarity of presentation and without loss of generality, liquefied natural gas 432 is used as an example of the liquid phase combustible refrigerant 132. Herein, a connection line 652 runs, at least partially, from the connector 650 to the heat exchanger 310, where the connection line 652 transports at least the liquefied natural gas 432 from the first storage tank 632 of the trailer 630 to the data center 110 and/or a region proximate, such as within less than 100, 50, 25, 10, 5, 4, 3, 2, or 1 foot from the processing unit 200 and preferably to an input connected of the heat exchanger 310. Again, as described supra, the generated heat 114 from the data center 110 and/or processing unit 200 therein is used to provide greater than 10, 20, 30, 40, 50, 60, 70, 80, or 90 percent of the energy of an enthalpy of vaporization of the refrigerant 130 and/or heat required to phase change 135 the liquid phase combustible refrigerant 134/liquefied natural gas 432 to the gas phase combustible refrigerant 136/gas phase natural gas 436, where the heat transfer 120 and optional subsequent movement of the gas phase natural gas away from the data center 110/processing unit cools the data center 110/processing unit 200.

### Example III

In a third example, referring now to FIG. 6C, a multi-truck system 670 of the vehicle assisted heat transfer system 600 is illustrated. Essentially, one or more and optionally all of the elements of the elements in the above described first and/or second examples are used. However, a second trailer 634 and/or a second storage tank 636 is used to resupply the liquefied natural gas 432 and/or the liquid phase combustible refrigerant 132 to the first storage tank 632. The resupply is optionally performed at any time, such as when fluid from the first storage tank 632 is being phase changed 134. Herein, a refill line 680 from the second storage tank 636 to the first storage tank 632 is used to transfer the fluid. Herein, a transfer line 670 includes any connection element between the first storage tank and the data center 110 and/or processing unit used to move fluid 520, such as through a connection line or intermediate heat transfer system 510, between the data center 110/processing unit 200 and the first storage tank 632 or vice versa.

### Example IV

In a fourth example, referring now to FIG. 6D, a ship heat transfer system 680 is illustrated. Generally, a ship 682 used to transport liquefied natural gas 432 is connected with the connection line or intermediate heat transfer system 510 to the data center 110, the processing unit 200, and/or to a zone of the generated heat 114. In a first case, the connection line or intermediate heat transfer system 510 moves/transfers 120 the generated heat 114 from the data center 110 and/or the processing unit 200 to the ship 682, where regasification occurs on the ship 682 to cool the data center 110 and/or the processing unit 200, as described supra, such as in a manner related to that described in Example I. In a second case, the connection line or intermediate heat transfer system 510 moves/transfers 120 the liquid phase combustible refrigerant 132 and/or the liquefied natural gas 432 from the ship 682 to the data center 110 and/or the processing unit 200, where regasification occurs on in/proximate the data center 110 and/or the processing unit 200 resultant in cooling of the data center 110 and/or an element therein, as described supra, such as in a manner related to that described in Example II. In this example, the processing unit 200 is illustrated on land and/or on a floating element 201, such as a barge and/or a ship.

### Example V

In a fifth example, referring now to FIG. 6E, a pipeline heat transfer system 690 is illustrated as an example of the liquid phase combustible refrigerant transfer system 610. Here, a pipeline 692, such as transporting liquefied natural gas 432, is used as a source of the liquefied natural gas 432 used to cool the data center 110, a server therein, and/or a processing unit 200. As illustrated, the pipeline 692 delivers the liquefied natural gas 432 or a combustible fuel, as a pipeline section 692 anywhere along the length of the pipeline 694 and/or at a pipeline terminus 696. Optionally and preferably, the data center 110 is positioned a distance from the transported liquid phase combustible refrigerant 132 and/or the liquefied natural gas 432, such as at a distance of less then 5000, 2500, 1000, 500, 250, 100, 50, 10, 5, or 1 foot. Similar distances are optionally employed for any liquid phase combustible refrigerant transfer system 610 to data center 110 system. Again, the connection line 510 moves/transfers 120 the generated heat 114 from the data center 110 to the pipeline 692 and/or moves the liquid phase combustible refrigerant 132 to the data center 110, where subsequent regasification cools the data center 110, such as described supra.

Several more examples are provided for clarity of presentation and without loss of generality, infra.

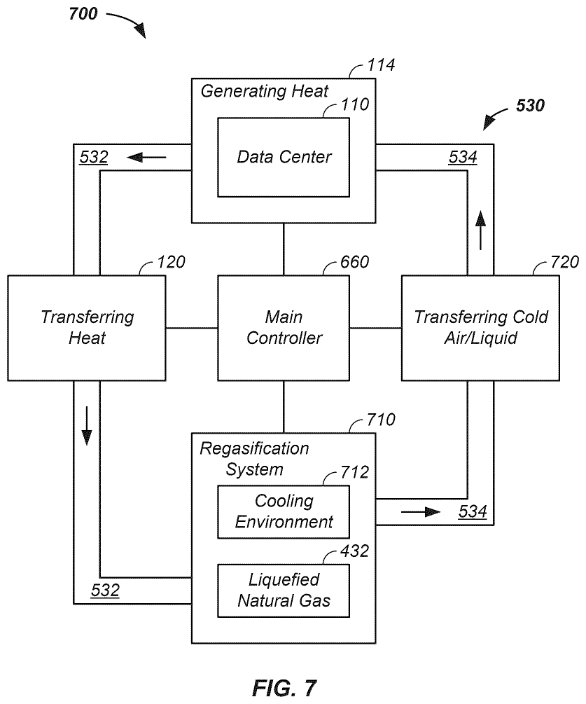

Referring now to FIG. 7, a circulating energy management system 700, which is an example of the energy management system 100, is illustrated, such as with a jointly operated heating and cooling system. Generally, a data center 110 generates waste heat, where the waste heat is used in a heating system for regasification of liquefied natural gas 432. Similarly, optionally at the same time, the regasification process cools a local environment, such as air and/or a liquid in a cooling system, where the cooled air/liquid is used to cool the data center 110. The jointly operated heating and cooling system is further described infra.

### Liquefied Natural Gas/Natural Gas

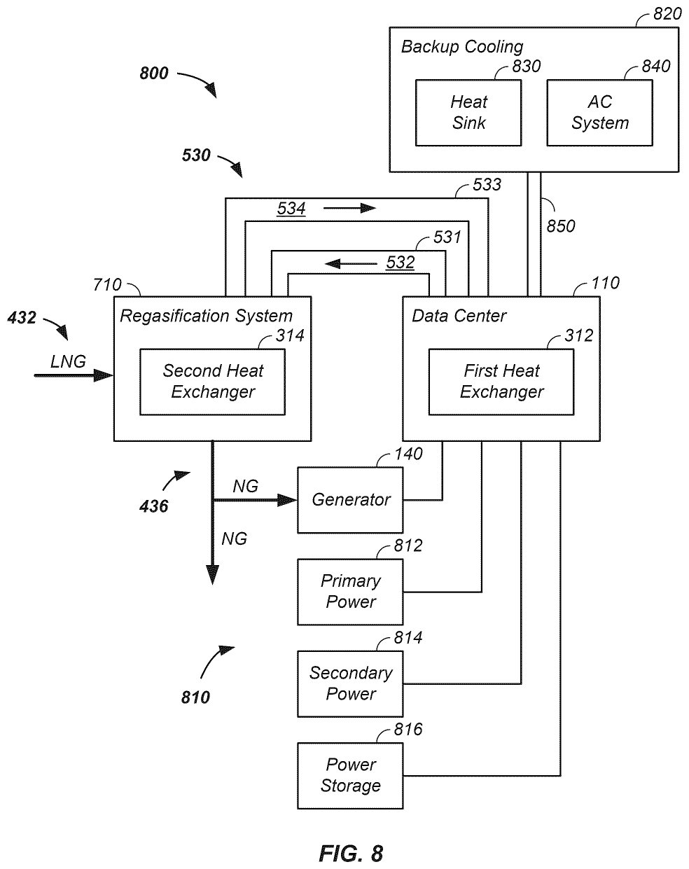

Still referring to FIG. 7 and referring now to FIG. 8, natural gas, when used for power generation, is typically taken out of the ground, and liquified for transport. Liquefied natural gas (LNG) 432 is natural gas (NG) 436, which is also referred to at NG (g) and/or gas phase natural gas, that has been cooled to a liquid state. Generally, at atmospheric pressure, natural gas 436 condenses into a liquid, called liquefied natural gas 432 at approximately −260° F. (−161.5° C.). Liquefied natural gas 432 is optionally produced, shipped, and/or used at low or high pressure. Prior to use, such as in a power generator, liquefied natural gas 432 needs to be regasified in a regasification system 710, where the liquefied natural gas 432 phase changes 135 and/or boils to form natural gas 436. The regasification process requires heat, such as provided by the waste heat generated by a data center 110, as described infra.

### Data Centers

Referring still to FIGS. 7 and 8, data centers 110 presently provide a tremendous amount of computational power, for governmental, military, and/or industrial use. However, data centers 110 generally use a substantial amount of power to run their processors for computation, such as in a server farm, which generates waste heat 114. In a first process of transferring heat 120, the heat is moved to a regasification system 710 where the heat is subsequently used to regasify liquefied natural gas 432 into natural gas 436, such as with a first heat exchanger 312 and/or an intermediate heat transfer system, such as described supra. This is one-half of the jointly operated heating and cooling system of the energy management system 100. The second half is described infra.

### Regasification System

Still referring to FIGS. 7 and 8, in the regasification system 710, when the liquefied natural gas 432 is going to be used, it needs to be regasified into natural gas 436. The regasification of the liquefied natural gas 432 into natural gas 436 in endothermic, requiring at least the enthalpy of vaporization, about 510 kJ/kg. Stated again, the enthalpy of vaporization is the heat energy needed to regasify or phase change the liquefied natural gas 432 to yield natural gas 436. As the liquefied natural gas 432 is brought back to gaseous phase to form the natural gas 436, such as at a reasonable pressure of ˜200 to 500 kPa (˜2 to 5 atm) the enthalpy, enthalpy of vaporization and/or the heat of vaporization, must be added to the liquefied natural gas 436 (LNG), such as from the heat from the data center 110. At the same time and/or alternatively subsequently, the heat of vaporization yields a second process of cooling a local environment, such as air, liquid, and/or a solid, such as a heat sink. The, now cooled air/liquid, is moved in a third process of transferring the cooled air/liquid 720 back to the data center 110 for cooling, such as through a first heat exchanger 312.

Still referring to FIG. 8, optionally and preferably a heated fluid 532 moves in a heat transfer pipe 531 from the data center 110 to the regasification system 710 and then a cooling fluid 534, optionally the same fluid, moves in a “cold transfer” pipe 533 from the regasification system 710 to the data center 110 and/or to an element therein.

Referring again to FIG. 7, a main controller 660, such as a computer/intelligent system/control program, is used to control any aspect of moving heat from the data center 110 to the regasification system 710 and/or for moving any cooled element from the regasification system 710 to the data center 110 and/or is used to control any aspect of the data center 110 and/or the regasification system 710.

### Example VI

In a sixth example, circulating fluid 530, such as in one or more fluid loops, is cooled by the conversion of liquefied natural gas 432 to the gas phase natural gas 436. Stated again, the heating of the liquified natural gas 432 and/or especially the enthalpy of converting the liquefied natural gas 432 to natural gas 436, is an endothermic process that takes heat from the surroundings. In this case, in the regasification system 710, the heat is taken from the circulating fluid 530, such as through the second heat exchanger 314, which cools the circulating fluid 530. The, now cooled, circulating fluid 530 is transferred 120 to the data center 110, where the cooled fluid, via a first heat exchanger 312, is used to draw waste heat 114 away from the data center 110, which heats the circulating fluid 530 and/or cools the data center 110. The, now heated, circulating fluid is optionally and preferably transferred 120 back to the regasification system 710, where cycle begins again with the now heated circulating fluid transferring heat to the liquefied natural gas 432, such as through the second heat exchanger 214.

### Example VII

Similarly, in a seventh example, at least one, heat transfer, fluid loop in used, where circulating fluid is heated by the waste heat/heat generated 114 from the data center 110, such as via the first heat exchanger 312. The now heated fluid is transferred 120/circulated to the regasification system 710, where the heated fluid releases heat, such as through the second heat exchanger 314, to heat the liquefied natural gas 432, which optionally not only heats the liquefied natural gas 432 but also converts the liquefied natural gas 432 to natural gas 436 for auxiliary use, such as for burning and providing power to any system on or off the power grid. The heated fluid is now cooled, such as by the endothermic natural gas phase change process, and is continued in a circulation path back to the first heat exchanger 312, where the cycle repeats starting with reheating the circulating fluid by the waste heat/heat generated 114 by at least one element in the data center 110.

As seen in the sixth and seventh examples, using the cooling power of the regasification of liquefied natural gas 432 as a heat dump for a data center 110 allows for the technologies to be coupled in a mutually beneficial manner. Furthermore, augmenting or replacing the power supplied to the data center for computation with a combination of natural gas generation, renewables and energy storage could allow the data center to be significantly more resilient to power and cooling source fluctuations.

### Resiliency/Backups

Still referring to FIG. 8, to build in resiliency for the data center 110, such as for the ability to ride through ebbs and flows of the liquefied natural gas supply, and or power outages, such as a black-out or brown-out, affecting the data center 110, adding at least one additional power source and/or a secondary backup cooling system 820/refrigeration mechanism is optional and preferable. For instance, waste energy 114 from the data center 110, such as stored in a heat sink 830, is used to drive an AC system 840. For instance, a heat transfer system 850 is used to move heat from the data center to the heat sink 830.

Referring again to FIG. 8, a power source 810, such as a primary grid power supply 812, is optionally and preferably backed up with a secondary power source 814, such as: any one or more of a solar array, a wind turbine, a hydro-electric power plant, and/or a battery system. A natural gas fed power generator 140 is also optionally used, such as in the event that the power has gone while the LNG/NG is still flowing. Optionally, the natural gas generated is used to drive another optional back-up system, such as by being used in electrolysis to form hydrogen gas, which is later burned to produce power. As for refrigeration a large scale heat exchanger or refrigeration unit is optionally employed. Here, optionally, the natural gas 436 could be used as the refrigerant. For example, methane, ˜95% of natural gas, is also known as the refrigerant R-50. A back-up cooling unit could be as simple as a closed loop with a compressor and an expansion region(s) running methane as the working fluid. For a data center, be it small (˜1 MW) or very large (˜100 MW), the cross over time switching power sources could be long enough that the data center could experience an unacceptably long outage period. To quell this we would propose adding an energy storage device that could be fast acting, to allow the power supply cross over to proceed without disruption. Such devices could include a battery bank, fly wheel, gravitational storage of weight (water), etc.

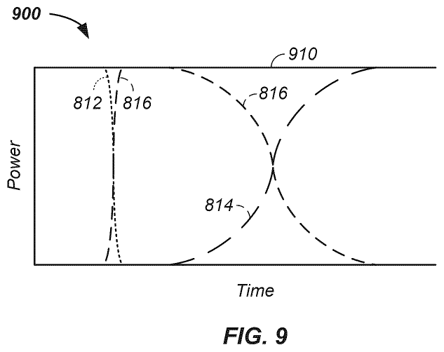

Referring now to FIG. 9, an internal control system, such as integrated with the main controller 660, optionally and preferably monitors the primary power and if there were a collapse in power, as the drop was detected, the power storage device would start to discharge it's stored power to keep the data center going. Simultaneously, the secondary power source would begin its start-up sequence. As the secondary power source came online, the draw from the stored power source would taper off. An illustrative exemplary plot of this process used in a constant power system 900 is provided in FIG. 9 where power from the primary power 812, secondary power 814, and power storage 816 are illustrated along with total power 810 as a function of time. The power storage 816 device would be recharged at a later time when smooth reliable power is again available.

### LNG to NG

After the liquefied natural gas is converted to gas phase natural gas, the gas is optionally re-pressurized to some value, such as for distribution. This pressure is optionally with 5, 10, or 20 percent of: 80 Bar (8.104 MPa, 1176 psi); 100 Bar (10.13 MPa, 1470 psi), or 120 Bar (12.56 MPa, 1764 psi). The density of liquefied natural gas is about 0.450 g/cm³, the density of gas state or gas phase natural gas is about 0.00065 g/cm³, where the ratio of these values is about 692. That is, natural gas in its gaseous form requires about 692 times the volume of liquefied natural gas. Given this, it is possible and might be advantageous to have the liquefied natural gas to undergo a phase change, gain heat to increase temperature, and then allow the natural gas to gain heat increasing temperature, pressure or both, at a certain constant volume, in an isochoric process, which allows the natural gas to remain pressurized whilst it takes heat, and also be pressurized appropriately to be ready for distribution.

The above isochoric process can be quantified using the specific heat capacity at constant volume, Cv. The ratio of these two specific heats is denoted with the lowercase Greek gamma, γ. In the case of natural gas, where the composition can vary, these ratios can be important in determining the heat required for the isochoric process. Referring now to Table 1, natural gas, natural gas constituents, and additional properties of the components are summarized. This is merely an example, and the ranges of the various constituents can vary depending how, where and when the natural gas was formed.

TABLE 1
Natural Gas

| | | | Boiling point | g = |
|---|---|---|---|---|
| Compound | formula | percentage | (° C.) | C_{P}/C_{V} |
| Methane | CH₄ | 85%-97% | −162 | 1.32 |
| Ethane | C₂H₆ | 0.9%-7% | −89 | 1.18 |
| Propane | C₃H₈ | 0.3%-5% | −42 | 1.13 |
| Butane | C₄H₁₀ | 0.2%-2% | −1 | 1.18 |
| Other (CO₂, | — | </≈2% | — | — |
| O₂, N₂, etc.) | | | | |

Some longer chain alkanes might be present in same natural gases, but they all have boiling points greater than room temperature; e.g. pentane Bₚ=36° C., it is well known for the alkanes as the number of carbons in the chain increases, so does the boiling point.

Optionally, there are cases where the selective removal, or enrichment, of one or more constituent is advantageous. Removal/enrichment is optionally achieved if the re-gasified natural gas product were to be transported in a geographic region where the ambient temperature was less than −1° C. most of the time, removing the butane from the mix as it would be in a liquid state while the other constituents would be in gas states.

Still yet another embodiment includes any combination and/or permutation of any of the elements described herein.

Herein, any number, such as 1, 2, 3, 4, 5, is optionally more than the number, less than the number, or within 1, 2, 5, 10, 20, or 50 percent of the number.

The particular implementations shown and described are illustrative of the invention and its best mode and are not intended to otherwise limit the scope of the present invention in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in a practical system.

In the foregoing description, the invention has been described with reference to specific exemplary embodiments; however, it will be appreciated that various modifications and changes may be made without departing from the scope of the present invention as set forth herein. The description and figures are to be regarded in an illustrative manner, rather than a restrictive one and all such modifications are intended to be included within the scope of the present invention. Accordingly, the scope of the invention should be determined by the generic embodiments described herein and their legal equivalents rather than by merely the specific examples described above. For example, the steps recited in any method or process embodiment may be executed in any order and are not limited to the explicit order presented in the specific examples. Additionally, the components and/or elements recited in any apparatus embodiment may be assembled or otherwise operationally configured in a variety of permutations to produce substantially the same result as the present invention and are accordingly not limited to the specific configuration recited in the specific examples.

Benefits, other advantages and solutions to problems have been described above with regard to particular embodiments; however, any benefit, advantage, solution to problems or any element that may cause any particular benefit, advantage or solution to occur or to become more pronounced are not to be construed as critical, required or essential features or components.

As used herein, the terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

Although the invention has been described herein with reference to certain preferred embodiments, one skilled in the art will readily appreciate that other applications may be substituted for those set forth herein without departing from the spirit and scope of the present invention. Accordingly, the invention should only be limited by the Claims included below.

1. A method for cooling a data center, comprising the steps of:
transferring a heat from the data center to a liquefied natural gas (LNG); and
phase changing the liquefied natural gas, the liquefied natural gas carried by a trailer, to a gas phase natural gas (NG), at least thirty percent of an enthalpy of vaporization energy used in said step of phase changing transferred to the gas phase natural gas in said step of transferring.

2. The method of claim 1, said step of phase changing occurring within two hundred feet of said trailer.

3. The method of claim 2, further comprising the steps of:
powering a cooling system with the gas phase natural gas generated in said step of phase changing; and
cooling the data center with said cooling system.

4. The method of claim 2, said step of transferring further comprising the steps of:
exchanging a portion of the heat into a heat transfer fluid;
moving the heat transfer fluid, carrying a portion of the heat from the data center to said trailer, the heat transfer fluid at a first temperature;
removing energy from the heat transfer fluid during said step of phase changing;
recirculating the heat transfer fluid at a second temperature from said trailer to the data center; and
repeating said steps of exchanging, moving the heat transfer fluid, removing energy, and recirculating the heat transfer fluid, said first temperature at least five degrees Fahrenheit warmer than said second temperature.

5. The method of claim 4, said step of phase changing further comprising the step of:
heating the liquefied natural gas, in said step of phase changing, at a position on said trailer.

6. The method of claim 5, further comprising the step of:
operating a generator positioned on said trailer with the gas phase natural gas generated in said step of phase changing.

7. The method of claim 6, further comprising the step of:
powering an element of the data center with said generator operating with the gas phase natural gas generated in said step of phase changing.

8. The method of claim 4, further comprising the step of:
refueling a first storage tank on said first trailer with replacement fuel from a second storage tank on a second trailer.

9. The method of claim 8, said step of refueling further comprising the step of
replenishing the liquid natural gas during said step of phase changing.

10. The method of claim 2, said step of transferring further comprising the steps of:
exchanging a portion of the heat from a heat sink in the data center to a heat transfer fluid;
transporting the heat transfer fluid to a position on said trailer;
moving energy from the heat transfer fluid into the liquefied natural gas in said step of phase changing;
recirculating the heat transfer fluid back to the data center; and
repeating said steps of exchanging, transporting, moving, and recirculating to cool the data center.

11. A method for cooling a data center, comprising the steps of:
transferring heat from the data center to a liquid phase combustible refrigerant; and
phase changing the liquid phase combustible refrigerant, carried by said trailer, to a gas phase combustible refrigerant, at least fifty percent of an enthalpy of vaporization energy used in said step of phase changing transferred to the gas phase combustible refrigerant in said step of transferring, the gas phase combustible refrigerant comprising an energy density of greater than 10,000 kJ/kg.

12. The method of claim 11, said step of phase changing further comprising the step of:
boiling a liquefied natural gas (LNG), carried by said trailer, to a gas phase natural gas (NG).

13. The method of claim 12, said step of transferring further comprising:
moving a heat transfer fluid carrying a portion of the heat from the data center to within two hundred feet of said trailer.

14. The method of claim 13, further comprising the steps of repetitively:
recirculating said heat transfer fluid from said trailer back to the data center; and
repeating said step of moving.

15. The method of claim 11, further comprising the step of:
powering a generator with the gas phase combustible refrigerant generated in said step of phase changing.

16. The method of claim 15, further comprising the step of:
storing energy generated with said generator.

17. The method of claim 1, further comprising the step of:
performing said phase changing step on a trailer.

18. A method for cooling a data center, a heat energy in the data center generated by a processing unit, comprising the steps of:
phase changing a liquid phase combustible refrigerant to a gas phase combustible refrigerant; and
transferring a portion of the heat energy from the data center to a site greater than fifty feet from the processing unit, said step of transferring further comprising the step of:
delivering to the liquid phase combustible refrigerant at least fifty percent of an energy of an enthalpy of vaporization of the liquid phase combustible refrigerant transferred to the liquid phase combustible refrigerant in said step of phase changing.

19. The method of claim 18, further comprising the step of:
providing said liquid phase combustible refrigerant with less than ten percent chloride by mass.

20. The method of claim 18, further comprising the step of:
providing said liquid phase combustible refrigerant with less than ten percent fluoride by mass.
